(19) United States
(12) Patent Application Publication
(10) Pub. No.: US 2024/0184960 A1
(43) Pub. Date: Jun. 6, 2024

(54) CALCULATION METHOD FOR DIKE BREACH DEVELOPMENT PROCESS

(71) Applicant: Changjiang River Scientific Research Institute, Wuhan (CN)

(72) Inventors: Wei Huang, Wuhan (CN); Duan Chen, Wuhan (CN); WenGang Duan, Wuhan (CN); YuFang Ni, Wuhan (CN); QingYuan Yang, Wuhan (CN); SiQi Wei, Wuhan (CN); QinXue Xia, Wuhan (CN)

(21) Appl. No.: 18/522,161

(22) Filed: Nov. 28, 2023

(30) Foreign Application Priority Data
Dec. 6, 2022 (CN) 2022115592073

(51) Int. Cl. G06F 30/28; G01V 99/00

(52) U.S. Cl. CPC G06F 30/28; G01V 99/00

(57) ABSTRACT

The invention provides a calculation method for dike breach development process, which relates to the field of flood disaster prevention. In this method, the influence of hydrodynamic on the development rate of the breach is considered, and the unit discharge of the breach is taken as the main parameter. The parameter expression between the hydrodynamic factors and the development process of the breach is established for both lateral widening and vertical downcutting. According to the invention, the whole development process of dike breach can be calculated with only a few parameters, and the main parameter unit discharge can be directly obtained by the discharge formula of broad crested weir. As the calculation incorporating as much physical mechanism as possible and simple calculation procedure, the method has high practicability, good repeatability and scientificity.

### TECHNICAL FIELD

The invention relates to the field of flood disaster prevention, in particular to a calculation method for dike breach development process.

### BACKGROUND

Dike, as an important part of flood control project, is widely used all over the world and plays an important role in social and economic development. However, as the flood beyond the prevention standard, the dike fails due to overtopping. The resulted flood will cause serious harm to people's lives and property in the inundation area. The process of dike breach is the interaction between dike materials and the flow through the breach. Quantitative analysis of the development rate of the breach is of great significance for the simulation of the dike breaching process, the prediction of the downstream flood propagation and the decision of the emergency evacuation plan.

At present, the existing techniques for calculating the breach development process are mainly divided into two categories. One is a parameter model based on data statistics, wherein, statistical methods are used to make regression analysis on the historical dike breach data, and empirical formulas are established for some key geometric and physical parameters of the breach, such as the widening rate of the breach, the downcutting rate of the breach, the shape of the breach and the time of the dike breaching. These formulas are relatively simple in structure and can be used to quickly evaluate the development process of the breach. However, the establishment of empirical formula usually needs a large number of measured data. Due to the danger and complexity of the dike breaching, the collected data are extremely limited and the accuracy of the data is poor, so the empirical formula has several limitations, and this kind of model does not involve the actual dike breaching mechanism, so the accuracy is low and the calculation results are unstable.

The other is a mathematical model based on physical mechanism, wherein, methods such as hydrodynamics and sediment transport are mainly used, and differential equations are used to describe the process of breach development and erosion, which can simulate the actual dike breaching process more accurate. However, this method is complicated to solve and contains some parameters that are not easy to be measured in the field, which limits the establishment and wide applicability of the equation.

For example, when studying the development of dike breaching breach, the method of soil mechanics is often used for reference, and the scour width (rate) of soil is expressed by water shear stress, critical shear stress and erosion coefficient, and the parameter expression of breach development process with shear stress as variable is established:

E=k_{d}Δt(τ−τ_{c}) or V_{z}=k_{d}(τ−τ_{d});
where E is scour depth, k_{d} is erosion coefficient, Δt is time, τ is average shear stress of flow, τ_{d} is the critical shear stress, and V_{z} is scour rate. Only when the flow shear stress is greater than the critical soil shear stress, soil will be washed away by flow. From the formula, it can be seen that the scour rate of the soil is not only affected by the hydrodynamic, but also related to the erosion coefficient and critical shear stress of the soil, and the erosion coefficient and critical shear stress are related to the properties of the soil itself. Among them, erosion coefficient is the most important parameter to determine the size of soil scour, and there are many empirical formulas to calculate the critical shear stress of different soils, and there is a certain relationship between them. However, when solving the flow shear stress, it is greatly influenced by the water depth; and the elevation of the bottom of the breach is difficult to measure because of the drastic change of the elevation, so it is impossible to accurately calculate the water depth. At the beginning of the dike breaching, the water depth is very small, and the water-sediment interface is more difficult to distinguish, which also makes it difficult to determine the water depth.

In addition to using the methods of soil mechanics, there is also a consideration of the effect of hydrodynamic on sediment erosion, and the relationship between the flow rate of breach and the downcutting rate and widening rate with Q as the main variable is established. However, the dike breaching process is a process of interaction between dike materials and breach flow, and the breach size affects the breach flow. In addition, breach flow can not truly reflect the effect of flow on sediment erosion, resulting in different forms and parameters of the expression of breach development rate and breach flow at different stages of dike breaching development; and the law of the relationship between breach development rate and breach flow at different inflow flows is also different.

Previous studies mainly focused on the mechanism, influencing factors and process of dike breaching, but no theoretical calculation model that can reasonably describe the breach development when the dike overflows and breaching has been put forward, and only a few related studies are qualitative analysis, without giving the decisive factors of breach development and the quantitative relationship expression between them.

### SUMMARY

In view of the above shortcomings in the current technology, the invention provides a calculation method for dike breach development process, and proposes to take the discharge per unit width of the breach qᵤₙᵢₜ as a variable. And the formulas for calculating the discharge per unit width of the breach, the lateral widening rate and the downcutting rate of the breach are established, which are suitable for the whole dike breaching process and the test conditions with different inflow flows.

The invention is realized by adopting the following technical scheme:

A calculation method for dike breach development process, wherein, the discharge per unit width of the breach is taken as the main parameter, and the parameter formula of the breach development process is established, which includes the following steps:
step 1: the dike breach flow is calculated according to the broad crested weir flow formula (1):

Q=μB\sqrt{2g}h^{1.5} (1)
μ—breach flow coefficient, dimensionless number;
Q—dike breach flow, in m³/s;
B—the width of the water surface at the breach, in m;
h is the water depth of the breach, in m;
step 2: based on the dike breach flow calculated in step 1, the discharge per unit width of the breach is calculated by Formula (2):

$${q}_{unit} = \frac{Q}{B} \qquad ( 2 )$$

qᵤₙᵢₜ—discharge per unit width of breach, m²/s;
step 3: based on the discharge per unit width of the breach calculated in step 2, the calculation formulas of the discharge per unit width of the breach, the lateral widening rate and the vertical downcutting rate of the breach are established;
step 4: based on the lateral widening rate and vertical downcutting rate of the breach calculated in step 3, the lateral widening development process and vertical downcutting development process of the breach are calculated respectively.

Further, step 3 specifically includes:
the lateral widening rate of the breach is calculated by Formula (3a):

$${γ}_{B} = {a}_{B} {e}^{{b}_{B ( {q}_{unit} - {q}_{unit c} )}} \qquad ( 3 a )$$

the vertical downcutting rate of the breach is calculated by Formula (3b):

$${γ}_{H} = {a}_{H} {e}^{{b}_{H ( {q}_{unit} - {q}_{unit c} )}} \qquad ( 3 b )$$

γ_{B}—lateral widening rate of breach, physical meaning is lateral widening width of breach per unit time, in m/s;
γ_{H}—vertical downcutting rate of breach, in m/s;
a_{B}, b_{B}, a_{H}, b_{H}—erosion coefficient and dimensionless parameter;
q_{unit c}—critical value of discharge per width of breach, which is related to the critical shear stress of soil and its own properties, in m²/s.

Further, step 4 specifically includes:
the lateral widening development process of breach is calculated by Formula (4a):

B_{t+Δt}=Bₜγ_{B}·Δt (4a)
the vertical downcutting development process of the breach is calculated by Formula (4b):

H_{t+Δt}=Z_{b0}−Z_{bt+Δt} (4b)
B_{t+Δt}—lateral width of breach at t+Δt moment, in m;
Bₜ—lateral width of breach at time t, in m;
H_{t+Δt}—vertical depth of breach at t+Δt moment, in m;
Z_{b0}—breach bottom elevation at initial 0 moment, in m;
Z_{bt+Δt}—breach bottom elevation at t+Δt moment, in m;
Δt—calculation time step of breach, in s;
the formula for calculating the elevation Z_{bt+Δt} at the breach bottom at t+Δt moment is as follows:

$$\begin{matrix}{Z}_{bt + Δ t} = {Z}_{bt} - {γ}_{H} \cdot Δ t \\ = {Z}_{bt} - {a}_{H} {e}^{{b}_{H} ( {q}_{unit} - {q}_{unit c} )} \cdot Δ t \\ = {Z}_{bt} - {a}_{H} {e}^{{b}_{H} ( μ \sqrt{2 g} {h}^{1.5} - {q}_{unit c} )} \cdot Δ t \\ = {Z}_{bt} - {a}_{H} {e}^{{b}_{H} ( μ \sqrt{2 g} ( Z - {Z}_{bt} ) - {q}_{unit c} )} \cdot Δ t\end{matrix} . \qquad ( 5 )$$

Further, the calculation formula of the lateral width B_{t+Δt} of breach at t+Δt moment is as follows:

$$\begin{matrix}{B}_{t + Δ t} = {B}_{t} + {γ}_{B} \cdot Δ t \\ = {B}_{t} + {a}_{B} {e}^{{b}_{B} ( {q}_{unit} - {q}_{unit c} )} \cdot Δ t \\ = {B}_{t} + {a}_{B} {e}^{{b}_{B} ( μ \sqrt{2 g} {h}^{1.5} - {q}_{unit c} )} \cdot Δ t \\ = {B}_{t} + {a}_{B} {e}^{{b}_{B} ( μ \sqrt{2 g} ( Z - {Z}_{bt} ) - {q}_{unit c} )} \cdot Δ t\end{matrix} \qquad ( 6 a )$$

that is:

B_{t+Δt}=Bₜ+a_{B}e^{b}^{_{B}}^{(μ\sqrt{2g}(Z-Z}^{_{bt}}^{)-q}^{_{unit c}}⁾·Δt (6b).

Further, the calculation formula of the vertical depth H_{t+Δt} of breach at t+Δt moment is as follows:

H_{t+Δt}=Z_{b0}−Z_{bt+Δt}=Z₀−Z_{bt}+a_{H}e^{b}^{_{H}}^{(μ\sqrt{2g}(Z-Z}^{_{bt}}^{)-q}^{_{unit c}}⁾·Δt (6c).

Compared with the current technology, the invention has the following advantages:
(1) Compared with the traditional empirical formula, the invention makes up for the shortcomings of unclear formula of breach development and lack of physical significance in the current technology, and the calculation method of breach development process provided by the invention has strong physical significance.
(2) The discharge per unit width of breach is consistent with discharge of breach in essence, but the discharge per unit width can more clearly explain the strength of hydrodynamic on sediment, avoid the influence of breach size on the hydrodynamic action of breach in different stages; in addition, it can formally describe the development process of breach in the whole dike breaching process, and establish a unified quantitative expression for the whole process, which can be used to calculate the whole process of lateral widening and vertical downcutting of breach; and it is suitable for different inflow flow test conditions.
(3) The calculation method provided by the invention requires few parameters, and the measured value involved in the calculation process is only the water level value, which is easy to obtain; and the calculation method has high practicability, good repeatability and scientificity, and the calculation process is simple.

### BRIEF DESCRIPTION OF DRAWINGS

FIG. 1 is a schematic diagram of the comparison between the calculated and the actually measured of the lateral width change process of the breach;

FIG. 2 is a schematic diagram of the comparison between the calculated and the actually measured of the vertical depth change process of the breach;

FIG. 3 is a flow chart of one embodiment of the method for calculating the breach development process of the present invention.

### DETAILED DESCRIPTION OF EMBODIMENTS

In order to make the purpose, technical scheme and advantages of the embodiment of the invention more clear, the technical scheme in the embodiment of the invention will be described clearly and completely with the attached drawings. Obviously, the described embodiment is a part of the embodiment of the invention, but not the whole embodiment. Based on the embodiments in the present invention, all other embodiments obtained by ordinary technicians in the field without creative work belong to the scope of protection of the present invention.

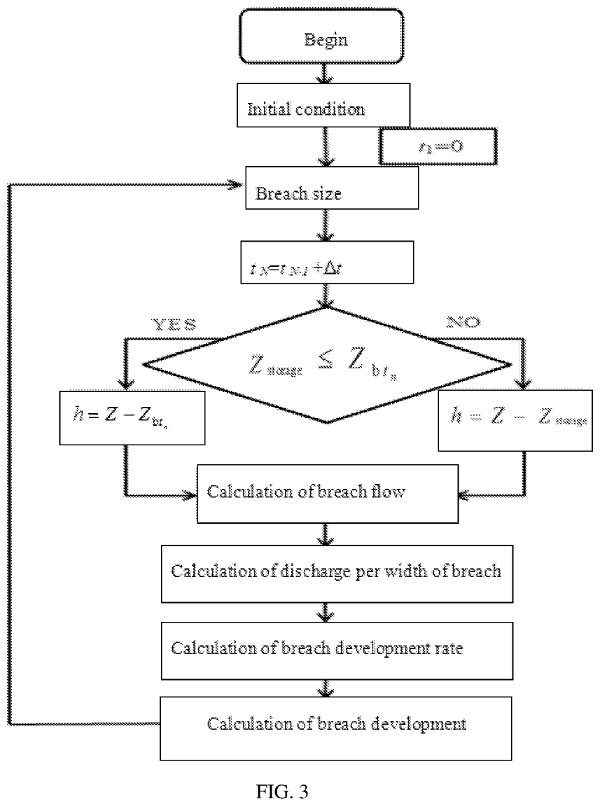

Please refer to FIG. 3. According to an embodiment of the present invention, a calculation method for dike breach development process is provided, which includes the following steps:
Step 1: the dike breach flow Q is calculated according to the broad crested weir flow formula (1):

Q=μB\sqrt{2g}h^{1.5} (1)
μ—breach flow coefficient, dimensionless number;
Q—breach flow, in m³/s;
B—the width of the water surface at the breach, in m;
h is the water depth of the breach, in m;
step 2: the discharge per unit width of the breach qᵤₙᵢₜ is calculated by Formula (2):

$${q}_{unit} = \frac{Q}{B} = μ \sqrt{2 g} {h}^{1.5} \qquad ( 2 )$$

qᵤₙᵢₜ—discharge per unit width of breach, m²/s;
h—the depth of the breach, in m, when the elevation at the bottom of the breach is higher than the downstream water level, that is, Z_{storage}≤Z_{bt}_{ₙ}, h=Z−Z_{bt}_{ₙ}, when the elevation at the bottom of the breach is lower than the downstream water level, that is, Z_{storage}>Z_{bt}_{ₙ}, h=Z−Z_{storage}; Z is the water level of the breach, and Z_{storage} is the water level downstream of the breach.
Step 3: the lateral widening rate of the breach γ_{B} is calculated by Formula (3a):

γ_{B}=a_{B}e^{b}^{_{B}}^{(q}^{ᵤₙᵢₜ}^{-q}^{_{unit c}}⁾=a_{B}e^{b}^{_{B}}^{(μ\sqrt{2g}h}^{^{1.5}}^{-q}^{_{unit c}}⁾ (3a)
the vertical downcutting rate of the breach γ_{H} is calculated by Formula (3b):

γ_{H}=a_{H}e^{b}^{_{H}}^{(q}^{ᵤₙᵢₜ}^{-q}^{_{unit c}}⁾=a_{H}e^{b}^{_{H}}^{(μ\sqrt{2g}h}^{^{1.5}}^{-q}^{_{unit c}}⁾ (3b)
γ_{B}—lateral widening rate of breach, in m/s;
γ_{H}—vertical downcutting rate of breach, in m/s;
a_{B}, b_{B}, a_{H}, b_{H}—erosion coefficient, dimensionless parameter;
q_{unit c}—critical value of discharge per width of breach, in m²/s.
Step 4: the lateral widening development process of breach is calculated by Formula (4a):

B_{t+Δt}=Bₜ+a_{B}e^{b}^{_{B}}^{(μ\sqrt{2g}(Z-Z}^{_{bt}}^{)-q}^{_{unit c}}⁾·Δt (4a)
the vertical downcutting development process of the breach is calculated by Formula (4b):

H_{t+Δt}=Z_{b0}−Z_{bt}+a_{H}e^{b}^{_{H}}^{(μ\sqrt{2g}(Z-Z}^{_{bt}}^{)q}^{_{unit c}}⁾·Δt (4b)
B_{t+Δt}—lateral width of breach at t+Δt moment, in m;
Bₜ—lateral width of breach at time t, in m;
H_{t+Δt}—vertical depth of breach at t+Δt moment, in m;
Z_{b0}—breach bottom elevation at initial 0 moment, in m;
Z_{bt+Δt}—breach bottom elevation at t+Δt moment, in m;
Δt—calculation time step of breach, in s.

Wherein, the calculation formula of the lateral width B_{t+Δt} of breach at t+Δt moment is as follows:

$$\begin{matrix}{B}_{t + Δ t} = {B}_{t} + {γ}_{B} \cdot Δ t \\ = {B}_{t} + {a}_{B} {e}^{{b}_{B} ( {q}_{unit} - {q}_{unit c} )} \cdot Δ t \\ = {B}_{t} + {a}_{B} {e}^{{b}_{B} ( μ \sqrt{2 g} {h}^{1.5} - {q}_{unit c} )} \cdot Δ t \\ = {B}_{t} + {a}_{B} {e}^{{b}_{B} ( μ \sqrt{2 g} ( Z - {Z}_{bt} ) - {q}_{unit c} )} \cdot Δ t\end{matrix} \qquad ( 6 a )$$

that is:

B_{t+Δt}=Bₜ+a_{B}e^{b}^{_{B}}^{(μ\sqrt{2g}(Z-Z}^{_{bt}}^{)-q}^{_{unit c}}⁾·Δt (6b).

The calculation formula of the vertical depth H_{t+Δt} of breach at t+Δt moment is as follows:

H_{t+Δt}=Z_{b0}−Z_{bt+Δt}=Z₀−Z_{bt}+a_{H}e^{b}^{_{H}}^{(μ\sqrt{2g}(Z-Z}^{_{bt}}^{)-q}^{_{unit c}}⁾·Δt (6c).

Next, the invention will be further explained with a specific application embodiment.

### (1) Test Conditions

The test system consists of river course, washable lateral dike, non-washable bottom plate and flood storage and detention area. The main river course is 10 m long and 1 m wide, and the washable lateral dike is parallel to the incoming flow direction, the non-washable bottom plate is 4.3 m long and 2.5 m wide. In the test, the water flowing through the dike breach can be freely discharged from the flood plain without affecting the flow of the breach. In all the tests, non-cohesive uniform sandy materials are used for dike construction, that is, uniform coarse sand with median particle size d₅₀=1 mm. Dike length L is 3 m, dike height is 0.3 m, dike top width W is 0.1 m, inner and outer dike slopes is 1:2 and dike bottom width is 1.3 m. In order to ensure the same location of the breaching due to overtopping, in the model, a rectangular initial notch with a depth of 0.02 m and a width of 0.85 m at the top of the dike from the upstream end is excavated.

### (2) Calculation of Breach Flow

Firstly, the lateral width B₀=0.1 m and the bottom elevation Z_{b0}=0.28 m of the initial breach are determined. The initial moment is the moment when the initial breach of the dike just overflows to zero, that is, t₁=0 s. With the water level z rising before the breach, the discharge per width of the breach increases and the breach begins to expand. The dike breach flow Q is calculated according to the broad crested weir flow formula (1):

Q=μB\sqrt{2g}h^{1.5} (1)
μ—breach flow coefficient, dimensionless number;

### (3) Calculation of Discharge Per Width of Breach

The discharge per unit width of the breach qᵤₙᵢₜ is calculated by Formula (2):

$${q}_{unit} = \frac{Q}{B} = μ \sqrt{2 g} {h}^{1.5} \qquad ( 2 )$$

At tₙ moment, the discharge per unit width of the breach is greater than the critical discharge per unit width, and the breach begins to expand. At this time, the elevation of the bottom of the breach is higher than the downstream water level, that is, Z_{storage}≤Z_{bt}_{ₙ}, h=Z−Z_{bt}_{ₙ}, and the discharge per unit width of the breach

$${q}_{unit} = \frac{Q}{B} = μ \sqrt{2 g} {h}^{1.5} = μ \sqrt{2 g} {( Z - {Z}_{{bt}_{n}} )}^{1.5} .$$

### (4) Calculation of Breach Development Rate

The lateral widening rate of the breach is calculated by Formula (3a):

$${γ}_{B} = {a}_{B} {e}^{{b}_{B} ( {q}_{unit} - {q}_{unit c} )} = {a}_{B} {e}^{{b}_{B} ( μ \sqrt{2 g} {h}^{1.5} - {q}_{unit} )} = {a}_{B} {e}^{{b}_{B} ( μ \sqrt{2 g} {( Z - {Z}_{{bt}_{n}} )}^{1.5} - {q}_{unit c} )} \qquad ( 3 a )$$

the vertical downcutting rate of the breach is calculated by Formula (3b):

$${γ}_{H} = {a}_{H} {e}^{{b}_{H} ( {q}_{unit} - {q}_{unit c} )} = {a}_{H} {e}^{{b}_{H} ( μ \sqrt{2 g} {h}^{1.5} - {q}_{unit c} )} = {a}_{H} {e}^{{b}_{H} ( μ \sqrt{2 g} {( Z - {Z}_{{bt}_{n}} )}^{1.5} - {q}_{unit c} )} \qquad ( 3 b )$$

### (5) Calculation of Breach Development Process

The lateral widening development process of breach at tₙ₊₁ moment is calculated by Formula (4a):

$${B}_{{t}_{n + 1}} = {B}_{{t}_{n}} + {a}_{B} {e}^{{b}_{B} ( μ \sqrt{2 g} ( Z - {Z}_{{bt}_{n}} ) - {q}_{unit c} )} \cdot Δ t \qquad ( 4 a )$$

The vertical downcutting development process of the breach is calculated by Formula (4b):

$${H}_{{t}_{n + 1}} = {Z}_{b0} - {Z}_{{bt}_{n}} + {a}_{H} {e}^{{b}_{H} ( μ \sqrt{2 g} ( Z - {Z}_{{bt}_{n}} ) - {q}_{unit c} )} \cdot Δ t \qquad ( 4 b )$$

At moment tₙ, the lateral width and vertical depth of the breach haven't changed, so Bₜ_{ₙ}=B₀=0.1, Z_{bt}_{ₙ}=Z_{b0}=0.28, the critical scour flow per unit width obtained from the experimental data are q_{unit c}=0.01 m²/s, a_{B}=0.00008, b_{B}=67.813, a_{H}=0.0004 and b_{H}=86.53, and they are substituted into formula (4a, b):

Bₜ_{ₙ₊₁}=0.1+0.0008e^{67.813(μ\sqrt{2g}(Z-0.28)}^{^{1.5}}^{-0.01)}·Δt (4c)

Hₜ_{ₙ₊₁}=0.0004e^{86.53(μ\sqrt{2g}(Z-0.28)}^{^{1.5}}^{-0.01)}·Δt (4d)

After calculation, the size of the breach at moment tₙ₊₁ is obtained as the initial breach size calculated in the next step. The above steps are repeated to calculate the size of the breach at moment tₙ₊₂. By repeating this step, the development process of the breach can be obtained.

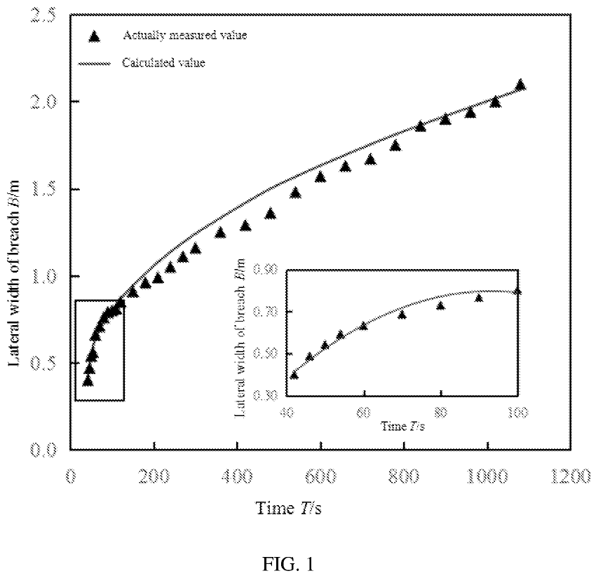

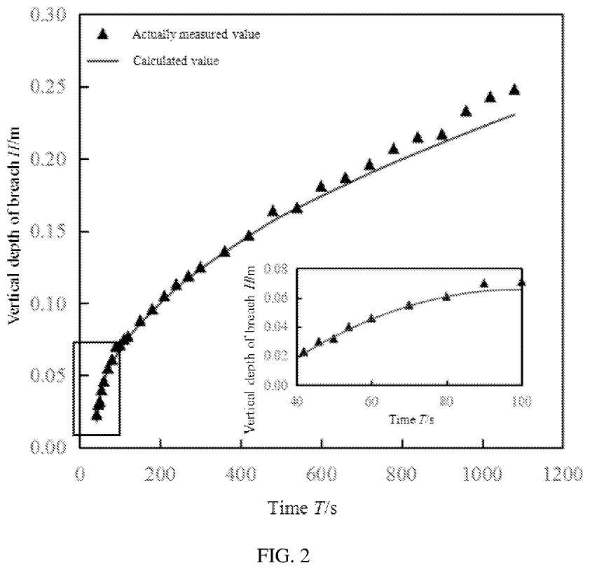

In this embodiment, the lateral width change process of the breach is shown in FIG. 1, and the vertical depth change process of the breach is shown in FIG. 2. As can be seen from FIG. 1 and FIG. 2, the breach topography obtained by using the calculation method of breach development process provided by the invention is highly consistent with the actually measured topographic data. Referring to the accuracy evaluation standard, the deterministic coefficient DC is used to express the degree of conformity between the calculation process and the actually measured process. 0≤DC≤1, and the closer DC is to 1, the better the degree of conformity between the calculation process and the actually measured process. The calculation formula is as follows:

$$D C = 1 - \frac{{{Σ}_{i = 1}^{n} [ {x}_{i} - {y}_{i} ]}^{2}}{{{Σ}_{i = 1}^{n} [ {y}_{i} - \overline{y} ]}^{2}} \qquad ( 5 )$$

Where: DC is the deterministic coefficient; xᵢ is the calculated value of the breach topography, yᵢ is the actually measured value of the breach topography, and y̅ is the average value of the actually measured values. The deterministic coefficient DC between the calculated value and the actually measured value of breach width is equal to 0.986; and the deterministic coefficient DC between the calculated value and the actually measured value of breach depth is equal to 0.989. It can be seen that the development process of breach topography calculated according to the comprehensive formula of breach development rate is in good agreement with the real development process of breach.

The invention provide a calculation method for dike breach development process, and relates to the field of flood disaster prevention. In this method, the influence of flow force on the development rate of the breach is considered, and the flow rate per width of the breach is taken as the main parameter, and the parameter expression between the flow elements and the development process of the breach is established, and two main development processes, lateral widening and vertical downcutting, are calculated. The calculation method for the development process of the breach provided by the invention has the advantages that: firstly, in the calculation method provided by the invention, the whole development process of the dike breaching of breach can be calculated, and is suitable for different inflow flow test conditions; secondly, the calculation method provided by the invention requires few parameters, and as the main parameter for calculating the development process of the breach, the discharge per unit width of the breach can be directly obtained from the flow formula of the broad crested weir, so that the calculation method has high practicability, good repeatability and scientificity, and the calculation process is simple; thirdly, the discharge per unit width of breach reflects the scouring effect of flow on sediment in breach. Based on the actual development mechanism of breach, the calculation formula established is more in line with the physical mechanism. According to the calculation method for dike breach development process provided by the invention, the relationship between the development rate of non-cohesive dike breach and hydraulic factors is clarified, and a quantitative relationship expression is established, which is of great significance for predicting dike breaching process and flood evolution.

The above is only the specific embodiment of the present invention, but the protection scope of the present invention is not limited to this, and any changes or substitutions that can be easily thought of by those skilled in the field within the technical scope disclosed by the present invention should be included in the protection scope of the present invention. Therefore, the scope of protection of the present invention should be based on the scope of protection of the claims.

What is claimed is:

1. A calculation method for dike breach development process, wherein, the discharge per unit width of the breach is taken as the main parameter, and the parameter formula of the breach development process is established, which includes the following steps:
step 1: the dike breach flow is calculated according to the broad crested weir flow formula (1):
Q=μB\sqrt{2g}h^{1.5} (1)
μ—breach flow coefficient, dimensionless number;
Q—dike breach flow, in m³/s;
B—the width of the water surface at the breach, in m;
h is the water depth of the breach, in m, when the water level outside the dike is lower than the elevation of the bottom of the breach, the water depth of the breach is the difference between the river water level and the elevation of the bottom of the breach; on the contrary, the water depth of the breach is the difference between the river water level and the water depth outside the dike;
step 2: based on the dike breach flow calculated in step 1, the discharge per unit width of the breach is calculated by Formula (2):
$${q}_{unit} = \frac{Q}{B} \qquad ( 2 )$$
qᵤₙᵢₜ—discharge per unit width of breach, m²/s;
step 3: based on the discharge per unit width of the breach calculated in step 2, the calculation formulas of the discharge per unit width of the breach, the lateral widening rate and the vertical downcutting rate of the breach are established;
step 4: based on the lateral widening rate and vertical downcutting rate of the breach calculated in step 3, the lateral widening development process and vertical downcutting development process of the breach are calculated respectively.

2. The calculation method for dike breach development process, as claimed in 1, wherein, step 3 specifically includes:
the lateral widening rate of the breach is calculated by Formula (3a):
$${γ}_{B} = {a}_{B} {e}^{{b}_{B ( {q}_{unit} - {q}_{unit c} )}} \qquad ( 3 a )$$
the vertical downcutting rate of the breach is calculated by Formula (3b):
$${γ}_{H} = {a}_{H} {e}^{{b}_{H ( {q}_{unit} - {q}_{unit c} )}} \qquad ( 3 b )$$
γ_{B}—lateral widening rate of breach, physical meaning is lateral widening width of breach per unit time, in m/s;
γ_{H}—vertical downcutting rate of breach, in m/s;
a_{B}, b_{B}, a_{H}, b_{H}—erosion coefficient, dimensionless parameter;
q_{unit c}—critical value of discharge per width of breach, which is related to the critical shear stress of soil and its own properties, in m²/s.

3. The calculation method for dike breach development process, as claimed in 2, wherein, step 4 specifically includes:
the lateral widening development process of breach is calculated by Formula (4a):
B_{t+Δt}=Bₜ+γ_{B}·Δt (4a)
the vertical downcutting development process of the breach is calculated by Formula (4b):
H_{t+Δt}=Z_{b0}−Z_{bt+Δt} (4b)
B_{t+Δt}—lateral width of breach at t+Δt moment, in m;
Bₜ—lateral width of breach at time t, in m;
H_{t+Δt}—vertical depth of breach at t+Δt moment, in m;
Z_{b0}—breach bottom elevation at initial 0 moment, in m;
Z_{bt+Δt}—breach bottom elevation at t+Δt moment, in m;
Δt—calculation time step of breaching, in s;
the formula for calculating the elevation Z_{bt+Δt} at the breach bottom at t+Δt moment is as follows:
$$\begin{matrix}{Z}_{bt + Δ t} = {Z}_{bt} - {γ}_{H} \cdot Δ t \\ = {Z}_{bt} - {a}_{H} {e}^{{b}_{H} ( {q}_{unit} - {q}_{unit c} )} \cdot Δ t \\ = {Z}_{bt} - {a}_{H} {e}^{{b}_{H} ( μ \sqrt{2 g} {h}^{1.5} - {q}_{unit c} )} \cdot Δ t \\ = {Z}_{bt} - {a}_{H} {e}^{{b}_{H} ( μ \sqrt{2 g} ( Z - {Z}_{bt} ) - {q}_{unit c} )} \cdot Δ t\end{matrix} . \qquad ( 5 )$$

4. The calculation method for dike breach development process, as claimed in 3, wherein, the calculation formula of the lateral width B_{t+Δt} of breach at t+Δt moment is as follows:
$$\begin{matrix}{B}_{t + Δ t} = {B}_{t} + {γ}_{B} \cdot Δ t \\ = {B}_{t} + {a}_{B} {e}^{{b}_{B} ( {q}_{unit} - {q}_{unit c} )} \cdot Δ t \\ = {B}_{t} + {a}_{B} {e}^{{b}_{B} ( μ \sqrt{2 g} {h}^{1.5} - {q}_{unit c} )} \cdot Δ t \\ = {B}_{t} + {a}_{B} {e}^{{b}_{B} ( μ \sqrt{2 g} ( Z - {Z}_{bt} ) - {q}_{unit c} )} \cdot Δ t\end{matrix} \qquad ( 6 a )$$
that is:
B_{t+Δt}=Bₜ+a_{B}e^{b}^{_{B}}^{(μ\sqrt{2g}(Z-Z}^{_{bt}}^{)-q}^{_{unit c}}⁾·Δt (6b).

5. The calculation method for dike breach development process, as claimed in 3, wherein, the calculation formula of the vertical depth H_{t+Δt} of breach at t+Δt moment is as follows:
H_{t+Δt}=Z_{b0}−Z_{bt+Δt}=Z₀−Z_{bt}+a_{H}e^{b}^{_{H}}^{(μ\sqrt{2g}(Z-Z}^{_{bt}}^{)-q}^{_{unit c}}⁾·Δt (6c).
